(19) United States
(12) Patent Application Publication
(10) Pub. No.: US 2025/0164890 A1
(43) Pub. Date: May 22, 2025

(54) LENS ELEMENT FOR A MICROLITHOGRAPHIC PROJECTION EXPOSURE APPARATUS DESIGNED FOR OPERATION IN THE DUV, AND METHOD AND ARRANGEMENT FOR FORMING AN ANTIREFLECTION LAYER

(71) Applicant: Carl Zeiss SMT GmbH, Oberkochen (DE)

(72) Inventor: Stephan SIX, Augsburg (DE)

(21) Appl. No.: 19/018,304

(22) Filed: Jan. 13, 2025

Related U.S. Application Data
(63) Continuation of application No. PCT/EP2023/066710, filed on Jun. 20, 2023.

(30) Foreign Application Priority Data
Jul. 11, 2022 (DE) 10 2022 207 068.2

(51) Int. Cl. G03F 7/00

(52) U.S. Cl. CPC G03F 7/70241; G03F 7/70258; G03F 7/70316

(57) ABSTRACT

The techniques disclosed herein relate to a lens element for a microlithographic projection exposure apparatus designed for operation in the DUV, and a method and an arrangement for forming an antireflection layer. In accordance with one aspect, in the case of a lens element according to the disclosed techniques, an antireflection layer is formed on a lens substrate, the antireflection layer comprising a first material of relatively lower refractive index and a second material of relatively higher refractive index, and a mixture ratio between the first material and the second material carrying in a lateral direction and/or in a vertical direction.

### CROSS REFERENCE TO RELATED APPLICATIONS

This is a Continuation of International Application PCT/EP2023/066710 which has an international filing date of Jun. 20, 2023, and the disclosure of which is incorporated in its entirety into the present Continuation by reference. This Continuation also claims foreign priority under 35 U.S.C. § 119(a)-(d) to and also incorporates by reference, in its entirety, German Patent Application DE 10 2022 207 068.2 filed on Jul. 11, 2022.

### FIELD

The techniques disclosed herein relate to a lens element for a microlithographic projection exposure apparatus designed for operation in the DUV, and to a method and an arrangement for forming an antireflection layer.

### BACKGROUND

Microlithography is used to produce microstructured electronic devices. The microlithography process is carried out in a so-called projection exposure apparatus, which comprises an illumination device and a projection lens. The image of a mask (i.e., a reticle) illuminated by the illumination device is projected by the projection lens onto a substrate (e.g., a silicon wafer) that is coated with a light-sensitive layer (photoresist) and is arranged in the image plane of the projection lens in order to transfer the mask structure to the light-sensitive coating on the substrate.

For antireflection layers, such as those used on lens elements in the DUV range (i.e., at wavelengths of, e.g., about 365 nm, about 248 nm or about 193 nm), the realization represents a demanding challenge in view of the increasingly stringent requirements regarding lithography systems (e.g., concerning the minimization of wavefront aberrations while providing the best possible antireflection effect over a wide wavelength range). FIGS. 5A-5B show a schematic illustration for elucidating a conventional method for forming an antireflection layer on a lens element substrate 501, wherein sublayers 502a, 502b of materials with different refractive indices from separate evaporation sources 511, 512 are applied in alternation. A problem that occurs in practice is that an increase in the number of sublayers in the layer construction of the respective antireflection layer is limited due to undesirable effects of a concomitant increase in thickness (in particular an increased radiation absorption and a resulting refractive index variation or wavefront aberration and also an increased deformation effect of the antireflection layer due to increasing line tension).

A further problem occurring in practice in terms of production when forming an antireflection layer of a curved (e.g., spherical) lens element is illustrated merely schematically in FIG. 6. Since during the formation of the antireflection layer 602 on a lens element substrate 601 (which as indicated in FIG. 6 is rotated about a spin rotation axis during the coating process) the material applied with an evaporation source 610 impinges at a considerably larger evaporation angle relative to the respective surface normal toward the lens element edge than in the lens element center, said formation of the antireflection layer at the lens element edge is formed with comparatively greater porosity. This circumstance in turn has an effect on the profile of the layer thickness (which is typically set in the coating process on the basis of achieving a desired mass applied). Without any stop effect, the layer thickness at the lens element edge is smaller than in the lens element center, but the porosity is higher and thus the layer thickness is not so much smaller as would be expected geometrically due to the dependence of the layer thickness on the cosine of the evaporation angle for the case that the material density at the center and the material density at the edge are the same. This undesirable effect—as indicated in the diagrams of FIGS. 7a-7d—can be counteracted by way of a redistribution of the material over the lens element surface using shading stops, but the optical performance remains impaired because of, among other things, a decrease in the refractive index toward the lens element edge due to the abovementioned porosity. By producing a greater layer thickness at the lens element edge compared to the lens element center, the values for reflection losses and polarization splitting occurring at the lens element edge can be approximated to the respective values in the lens element center. However, due to the lower refractive indices at the lens element edge, the optical performance of the antireflection layer in the lens element center cannot be fully achieved. For example, according to FIGS. 7A-7D, an antireflection layer which is thicker by 7% and is more porous, and thus less refractive, has sublayers that exhibit higher transmission losses through reflection and higher polarization splitting at large angles of incidence compared to the antireflection layer in the lens element center.

For the state of the art, reference is made only by way of example to DE 10 2016 200 814 A1, DE 10 2012 215 359 A1, M. F. Schubert et al.: “Performance of antireflection coatings consisting of multiple discrete layers and comparison with continuously graded antireflection coatings”, Applied Physics Express 3 (2010) 082502-1 to 082502-3 and M. Jupe et al.: “Laser-induced damage in gradual index layers and rugate filters”, Proc. OF SPIE Vol. 6403,: 2006, 640311-1 to 640311-13 (15. Jan. 2007); doi: 10.1117/12.696130.

### SUMMARY

It is an object of the techniques disclosed herein to provide a lens element for a microlithographic projection exposure apparatus designed for operation in the DUV, and a method and an arrangement for forming an antireflection layer, which enable an improved optical performance under at least partial avoidance of the problems described above.

According to one aspect, the disclosed techniques relate to a lens element for a microlithographic projection exposure apparatus designed for operation in the DUV,
wherein an antireflection layer is formed on a lens element substrate of this lens element,
wherein the antireflection layer has a first material of relatively lower refractive index and a second material of relatively higher refractive index, and
wherein a mixing ratio between the first material and the second material varies in the lateral direction and/or in the vertical direction.

The disclosed techniques are based on, in particular, the concept of designing an antireflection layer of a comparatively lower refractive index material and a comparatively higher refractive material on a lens element intended for use in a microlithographic projection exposure apparatus designed for operation in the DUV in such a way that the mixing ratio between these materials varies in the lateral direction and/or in the vertical direction.

Here and in the following text, “lateral direction” is understood to mean a direction parallel to a layer (i.e., along the surface of the antireflection layer), and “vertical direction” is understood to mean a direction perpendicular to the plane of a layer or to the lateral plane (i.e., a direction in the stack direction).

The disclosed techniques firstly comprise embodiments in which said variation of the mixing ratio is achieved by simultaneous evaporation (co-evaporation) from separate evaporation sources with a varying evaporation rate in each case, wherein this variation of the respective evaporation rate of the two materials is accompanied by a variation of the respective coated lens element substrate region from the lens element center toward the lens element edge. According to this approach, as will be explained in more detail below, the undesirable effect of a manufacturing-related increasing porosity of the antireflection layer toward the lens element edge can be compensated for insofar as an undesirable decrease in refractive index toward the lens element edge, which accompanies the increase in porosity, is counteracted by increasing the corresponding evaporation rate of the higher refractive material.

Furthermore, the disclosed techniques also comprise embodiments in which said variation of the mixing ratio is implemented in the vertical direction (i.e., perpendicular to the lateral direction), achieving the aim of the best possible antireflection effect over a comparatively large angle of incidence range with relatively low total thickness of the antireflection layer (and thus avoiding the problems associated with larger total layer thicknesses mentioned in the introductory part). For this setting of the mixing ratio varying in the vertical direction, in turn, the present disclosed techniques comprise embodiments in which the difficulties arising with a variable closed-loop control of the evaporation rate are avoided in that, with the realization of an evaporation of the respective materials at a constant evaporation rate, the variation of the mixing ratio of the materials according to the disclosed techniques is achieved by a targeted setting of the opening duration of shutters respectively assigned to the evaporation sources.

In other words, according to the disclosed techniques, using a suitably synchronized change between the opening state and closing state of a shutter for the respective materials (i.e., the higher refractive material on the one hand and the lower refractive material on the other), an effective evaporation rate which varies with time or with the increasing formation of the antireflection layer is set even though the respective evaporation rates of the separate evaporation sources themselves remain constant over time.

In this case, the two concepts mentioned above, namely the compensation of the effect of a porosity increasing toward the lens element edge during the formation of the antireflection layer on one hand and the generation of the best possible antireflection effect over a wide angle of incidence range with comparatively low total thickness of the antireflection layer on the other, can also be advantageously combined with each other. For example, in an antireflection layer designed for a wavelength of 365 nm, a decrease in the refractive index of a higher refractive Al₂O₃ sublayer from a value n₀=1.72 in the lens element center to a value n₁=1.52 at the lens element edge (see also FIG. 7A) can be compensated by a co-evaporation of HfO₂ with a refractive index of 2.1, and thus the same optical performance as in the lens element center can be achieved (FIGS. 7B and 7c). Taking into account that the refractive index for HfO₂ also decreases, due to the increasing porosity toward the lens element edge, in the same ratio as for Al₂O₃ from a value of 2.1 by 12% up to the lens element edge to a value n₂=1.85, a mixing ratio of 60% HfO₂ to 40% Al₂O₃ at the lens element edge must be selected (because the refractive index (1−x)*n₁+x*n₂ resulting according to the mixing ratio x=0.6 corresponds approximately to the value n₀=1.72 of the Al₂O₃ in the lens element center).

Thus, the disclosed techniques include embodiments in which, for a substantially constant optical performance (and in particular a constant mean refractive index) over the entire lens element surface from the lens element center to the lens element edge, is achieved by varying the mixing ratio of higher refractive and lower refractive material in the lateral direction by way of compensating said porosity increase toward the lens element edge. Moreover, the disclosed techniques include embodiments in which a good antireflection effect over a wide angle of incidence range with comparatively low total thickness of the antireflection layer is achieved by varying the mixing ratio between higher and lower refractive materials in the vertical direction (using the abovementioned synchronized opening or closing of a shutter at a constant evaporation rate of separate evaporation sources).

According to one embodiment, the lens element has at least one curved lens element surface. In particular, the lens element may also be a cylindrical lens element.

The disclosed techniques also relate to a microlithographic projection exposure apparatus having at least one lens element having the features described above.

The disclosed techniques further relate to a method for forming an antireflection layer on a lens element substrate of a lens element for a microlithographic projection exposure apparatus designed for operation in the DUV,
wherein the antireflection layer is formed from a first material of relatively lower refractive index and at least one second material of relatively higher refractive index,
wherein a mixing ratio between the first material and the second material is varied in the lateral direction and/or in the vertical direction.

According to one embodiment, the antireflection layer is formed using separate evaporation sources for the first and second materials, from which the respective material is supplied via a respectively intermittently open shutter.

According to one embodiment, the evaporation sources are operated at a constant evaporation rate, wherein a variation of the mixing ratio is achieved by a targeted setting of the opening duration of the shutter.

According to one embodiment, a simultaneous evaporation from the evaporation sources is carried out, wherein an increase in the evaporation rate of the second material compared to the evaporation rate of the first material is synchronized with a variation of the respective currently coated region of the lens element substrate. In this synchronization, in particular the evaporation rate of the second material compared to the evaporation rate of the first material, can be increased in the direction from a central region of the lens element to an edge region of the lens element.

According to one embodiment, the variation of the respective coated region of the lens element substrate is implemented by variation of the relative position of an opening aperture located in a shading stop with respect to the lens element.

The disclosed techniques further relate to an arrangement for forming an antireflection layer on a lens element substrate of a lens element for a microlithographic projection exposure apparatus designed for operation in the DUV,
comprising a first evaporation source for a first material of relatively lower refractive index and a second evaporation source for a second material of relatively higher refractive index,
wherein a separate shutter is assigned in each case to the first evaporation source and the second evaporation source; and
wherein a device configured to provide intermittent opening of these shutters is provided.

According to one embodiment, the arrangement further comprises a shading stop and a device configured to vary the relative position of an opening aperture located in this shading stop with respect to the lens element.

According to one embodiment, the arrangement is configured to implement the variation of the position of the opening aperture relative to the lens element in synchronization with an increase in the evaporation rate of the second material compared to the evaporation rate of the first material.

Further embodiments of the disclosed techniques are evident from the description and the claims.

The disclosed techniques are explained in more detail below with reference to an exemplary embodiment shown in the attached figures.

### BRIEF DESCRIPTION OF THE DRAWINGS

In the Figures:

FIGS. 1-2 show schematic illustrations for explaining a method for forming an antireflection layer on a lens element substrate according to one embodiment of the disclosed techniques;

FIG. 3 shows a schematic illustration for explaining a method for forming an antireflection layer on a lens element substrate according to a further embodiment of the disclosed techniques;

FIG. 4 shows a schematic illustration explaining the possible construction of a microlithographic projection exposure apparatus designed for operation in the DUV;

FIGS. 5A-5B show schematic illustrations for explaining a conventional method for forming an antireflection layer on a lens element substrate;

FIG. 6 shows a schematic illustration for explaining a problem occurring in a conventional method for forming an antireflection layer on a lens element substrate; and

FIGS. 7A-8C show schematic illustrations for explaining problems occurring in conventional methods for forming an antireflection layer on a lens element substrate.

### DETAILED DESCRIPTION

In the following text, different embodiments of the implementation of an antireflection layer on a lens element substrate of a lens element, which is intended for use in a microlithographic projection exposure apparatus designed for operation in the DUV, are described. These embodiments have in common that a respective mixing ratio between a first material of relatively lower refractive index and a second material of relatively higher refractive index is varied, wherein this variation is implemented during the generation of the antireflection layer in the lateral and/or vertical direction depending on the exemplary embodiment.

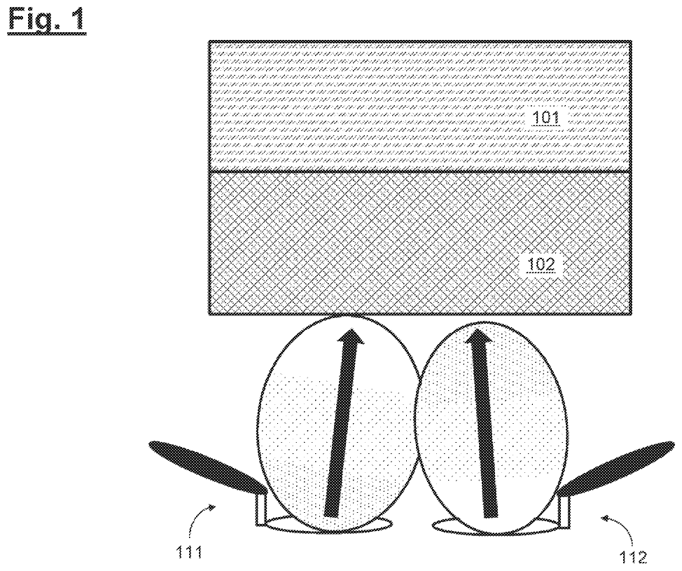

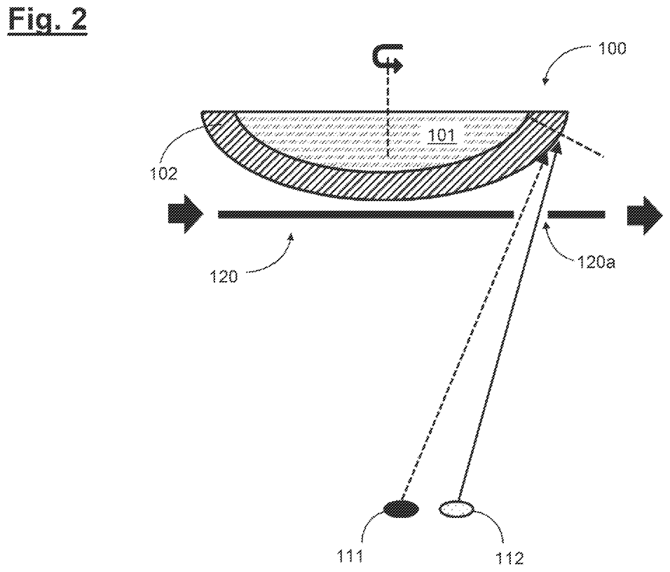

FIG. 1 and FIG. 2 first show schematic illustrations for explaining a method for forming an antireflection layer on a lens element substrate denoted with “101,” wherein a first evaporation source 111 having a first material of relatively lower refractive index and a second evaporation source 112 having a second material of relatively higher refractive index are used. The formation of the antireflection layer denoted with “102” is carried out by generating a mixing ratio which varies in the lateral direction. Materials of relatively lower refractive index are MgF2, AlF3, SiO₂, chiolite (Na₅Al₃F₁₄) or cryolite (Na₃AlF₆). Materials of relatively higher refractive index that can be used are LaF₃ or oxide materials such as Al₂O₃, HfO₂, TiO₂ or ZrO₂—depending on the working wavelength of the optical system or the projection exposure apparatus, wherein preferably higher refractive fluoridic materials should be mixed with low-refractive fluoride materials and higher refractive oxide materials should be mixed with lower refractive oxide materials.

The generation of a mixing ratio which varies in the lateral direction is implemented in such a way that, firstly during the coating process (in which the lens element substrate 101 rotates about a spin rotation axis as indicated in FIG. 2), the relative position of an opening aperture 120a located in a shading stop 120 with respect to the lens element substrate 101 varies by shifting the shading stop 120, wherein simultaneously (i.e., synchronized with said variation of the relative position and the associated variation of the respective currently coated region from the lens element center to the lens element edge) the respective evaporation rates of the first and second materials are changed. In embodiments, the lens element 100 comprising the lens element substrate 101 and the antireflection layer 102 may also be a cylindrical lens element (which proceeding from FIG. 2 extends into the drawing plane), in which case the previously described rotation of the lens element substrate 101 is omitted.

Typical evaporation rates for suitable thermal evaporation processes such as electron beam evaporation and thermal boat evaporation lie in the range of 0.05 nm/s and 2 nm/s, preferably in the range of 0.2 nm/s to 0.5 nm/s. For wavelengths in the range of 193 nm to 365 nm, the single layer thicknesses for antireflection coatings lie in the range of 2 nm to 200 nm, preferably in the range of 30 nm to 60 nm. This means that typical coating durations range from 60 s to 300 s, and for a diameter of the opening aperture 120a of 10 mm, the shifting in the lens element center must take place at a speed of 10 mm per minute to 2 mm per minute and be correspondingly slower toward the lens element edge.

Provided the evaporation rate of the first material is denoted with α, the refractive index of the first material is denoted with n₁, the evaporation rate of the second material is denoted with β, and the refractive index of the second material is denoted with n₂, then the following applies for the refractive index of the resulting antireflection layer:

$$\frac{α \cdot {n}_{1} + β \cdot {n}_{2}}{α + β}$$

The change in the evaporation rates α, β is implemented in such a way that the evaporation rate of the comparatively higher refractive second material relative to the evaporation rate of the lower refractive material is increased toward the lens element edge. As a result, the undesirable effect described in the introductory part of increasing porosity due to the evaporation angle increasing toward the lens element edge can be compensated for with regard to the effect on the resulting mean refractive index and thus the optical performance of the lens element.

At the same time, an undesirable variation in thickness during the formation of the antireflection layer can be reduced, which would otherwise result from the fact that, as a result of the greater porosity toward the lens element edge, achieving a target mass typically significant for the termination of the coating process occurs only later and thus only at a higher thickness. If the higher refractive material used according to the disclosed techniques is selected such that its density is also greater in comparison with the lower refractive material, the target mass relevant for the termination of the sealing process is also correspondingly achieved earlier toward the lens element edge, so that the above-mentioned thickness profile is compensated.

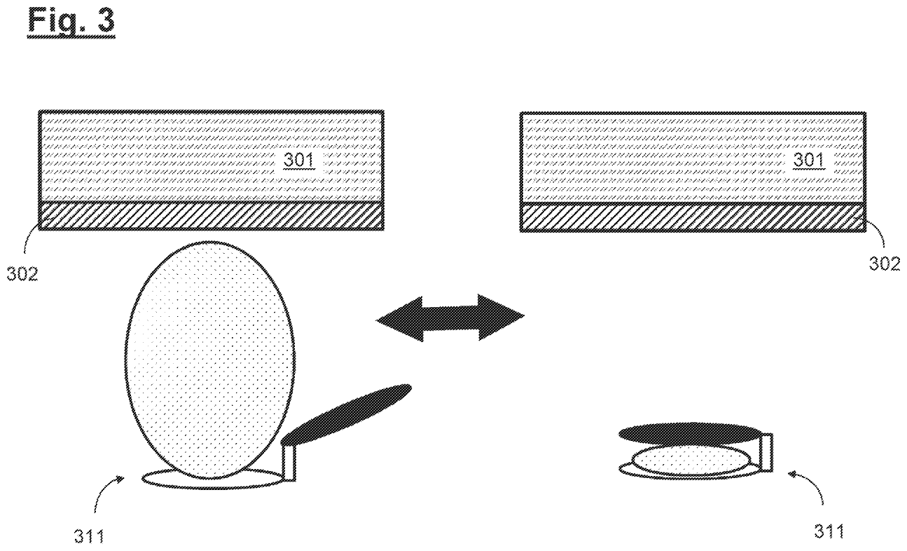

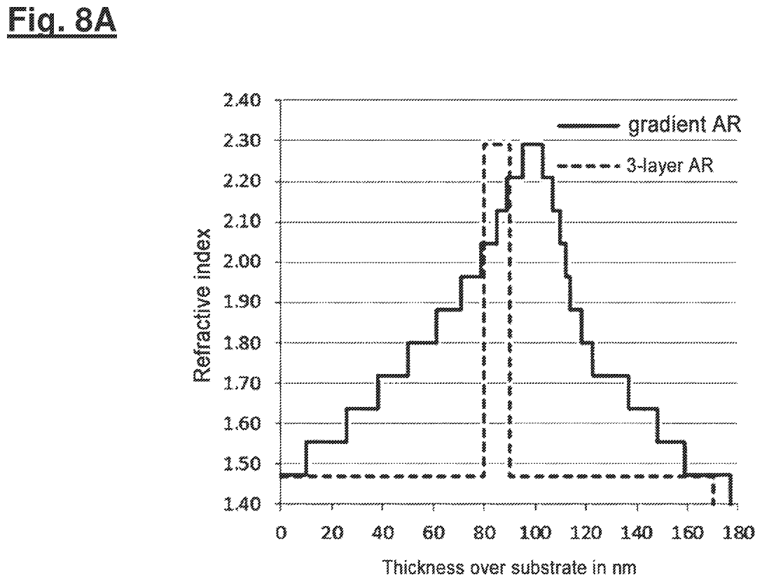

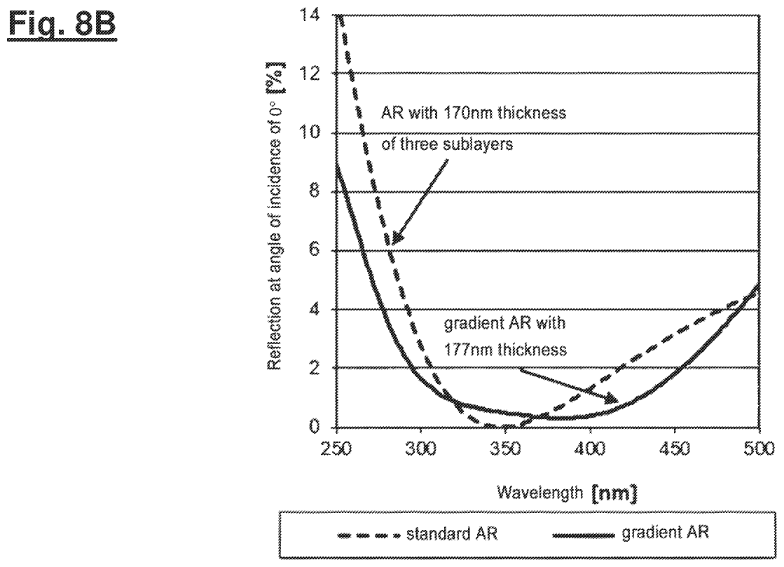

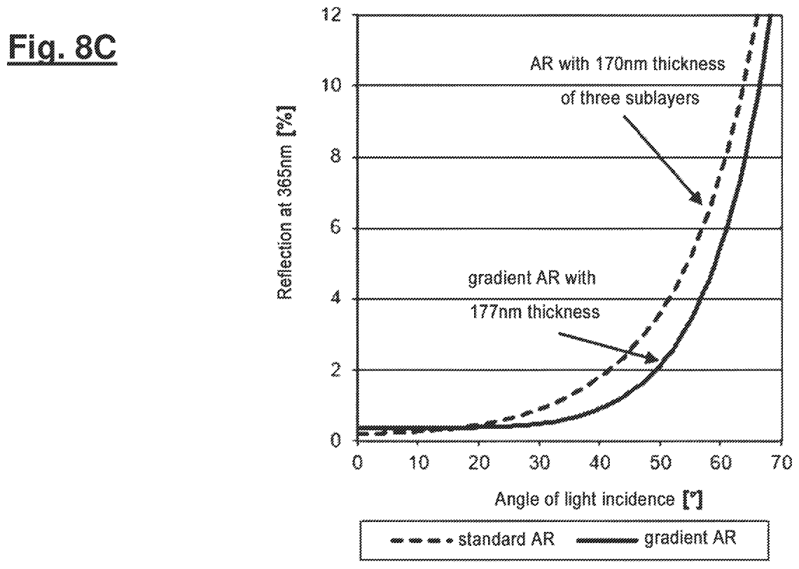

FIG. 3 shows a schematic illustration for explaining a further exemplary embodiment, wherein the variation of the mixing ratio according to the disclosed techniques is here implemented in the vertical direction with the aim, as indicated in FIGS. 8A-8C, of achieving the highest possible antireflection effect over a wide angle of incidence range also with a comparatively low total layer thickness of the antireflection layer. For a microlithographic projection exposure apparatus, typical angle of incidence ranges can extend from 0° to 60°, wherein up to an angle of incidence of 300 the reflection should not exceed 0.1%. The total layer thickness should be less than 200 nm, preferably less than 100 nm, in order to avoid lens element heating due to layer absorption and lens element deformations and crack formation in layers due to layer stresses.

According to FIG. 3, an intermittent shading of the respective evaporation source (denoted in FIG. 3 with “311”) is carried out to vary the mixing ratio, wherein the respective opening duration of a shutter used for this purpose is settable in a targeted manner. As a result, it can be ensured even when the evaporation source 311 is operated at a constant evaporation rate that the “effective rate” at which the material in question is supplied to the lens element substrate 301 for forming the antireflection layer 302 is varied.

If the shutter is open for a period of time t₁ and closed for a period of time, t₂ then, at a constant evaporation rate β of the evaporation source 311, an effective rate is obtained of

$$\frac{β \cdot {t}_{1}}{{t}_{1} + {t}_{2}}$$

By suitably setting the ratio of opening duration t₁ (during which the lens element substrate 301 undergoes evaporation) to shading duration t₂, it is possible to set any effective rate between zero and a constant valueβ according to the rate of the evaporation source 311. In this case, the change between opening and closing of the shutter is preferably carried out so quickly that approximately one atomic monolayer of the material in question is applied in a cycle. In this case, a substantially continuous gradient mixing layer can be produced from different materials. At typical evaporation rates in the range from 0.05 nm per second to 0.2 nm per second, the switch between opening and closing the shutter must then take place every one to four seconds.

The use of separate evaporation sources with a constant evaporation rate in each case is advantageous in that the difficulties typically associated with a continuous closed-loop evaporation rate control can be avoided.

As already mentioned, the variation of the mixing ratio of higher refractive and lower refractive material according to the disclosed techniques in the lateral direction (from the lens element center to the lens element edge) can also be combined with a variation of the mixing ratio between higher refractive and lower refractive material in the vertical direction. Such a combination may be implemented in order to achieve, even in the case of a possibly strongly curved lens element, a substantially consistent optical performance across the lens element surface from the lens element center to the lens element edge (as a result of the “lateral variation”), as well as (as a result of the “vertical variation”) a good antireflection effect over a wide angle of incidence range with comparatively low total thickness of the antireflection layer.

Here, starting from the embodiment described with reference to FIG. 2, in each case with a temporarily standing shading stop 120 or temporarily constant position of the opening aperture 120a located in this shading stop 120, as described above with reference to FIG. 3, it is possible to produce a gradient mixing layer of different materials with variation of the mixing ratio in the vertical direction (cf. FIG. 8A).

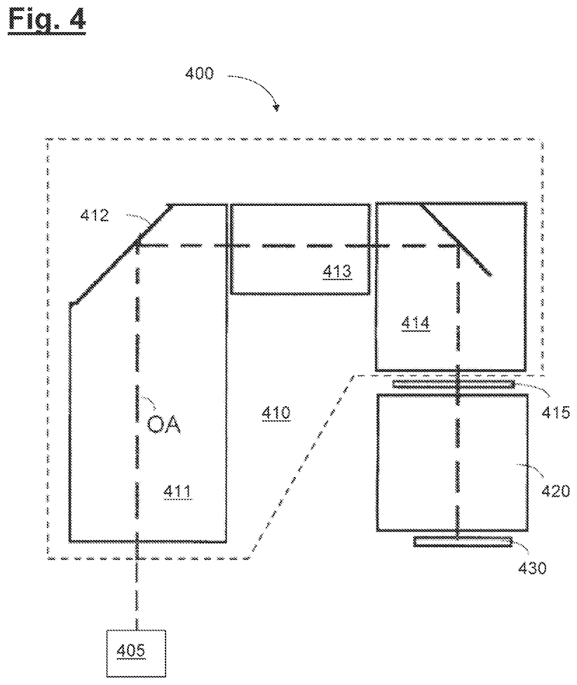

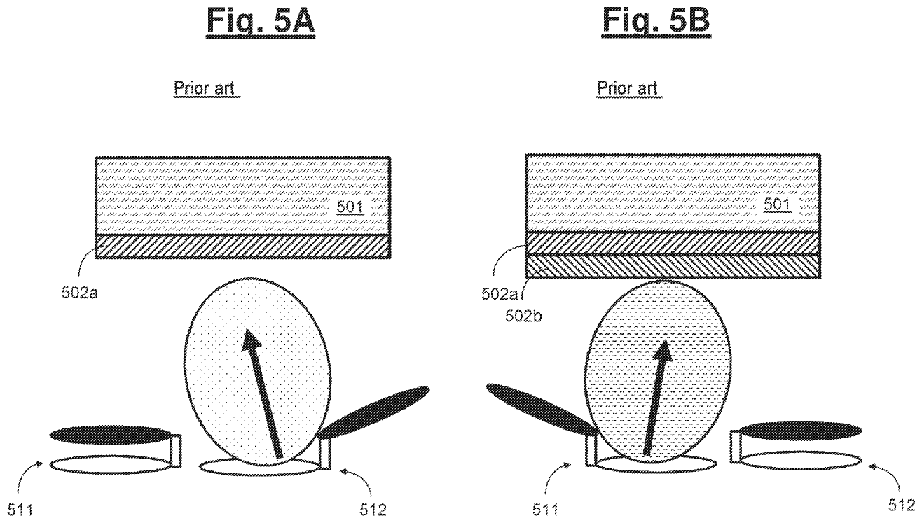

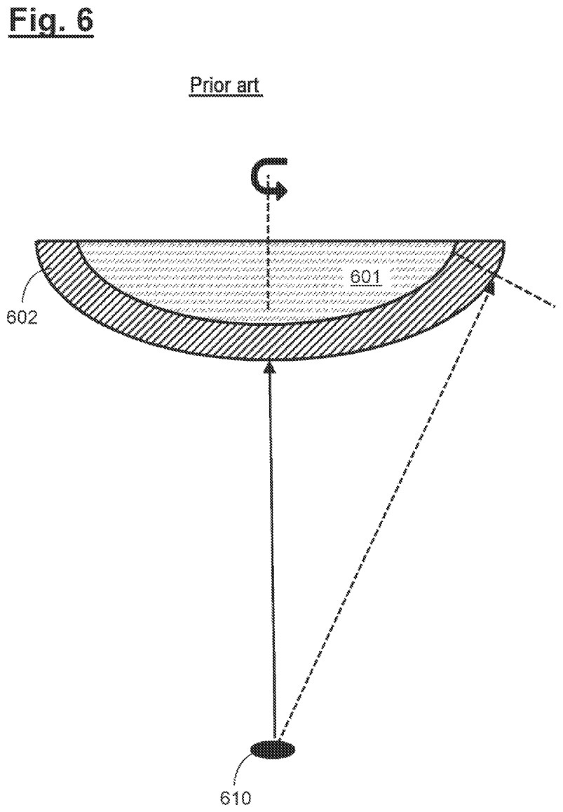

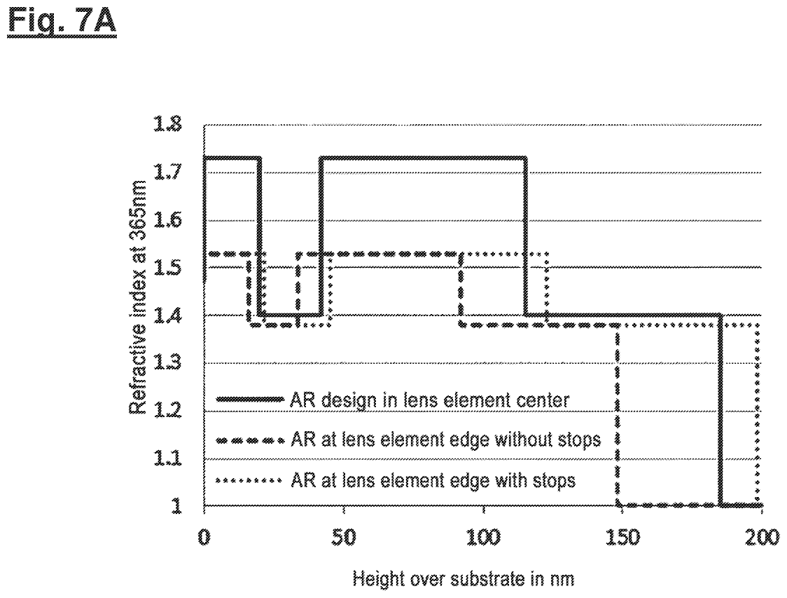

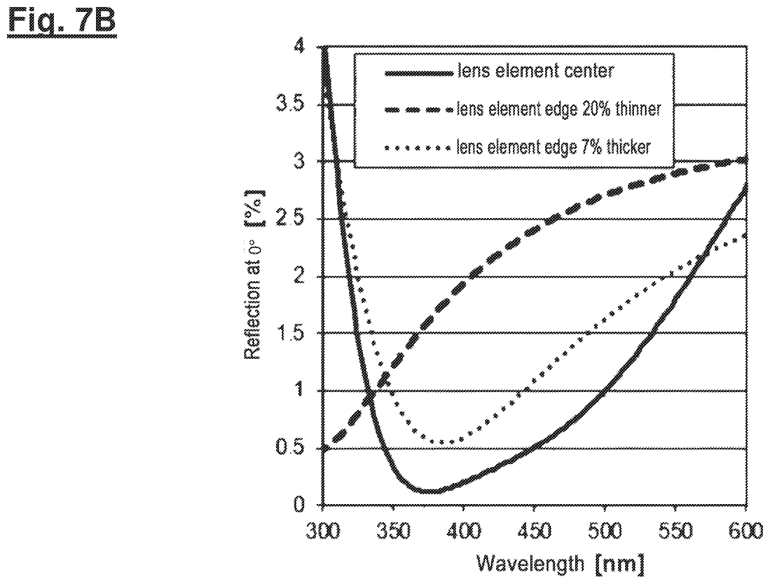

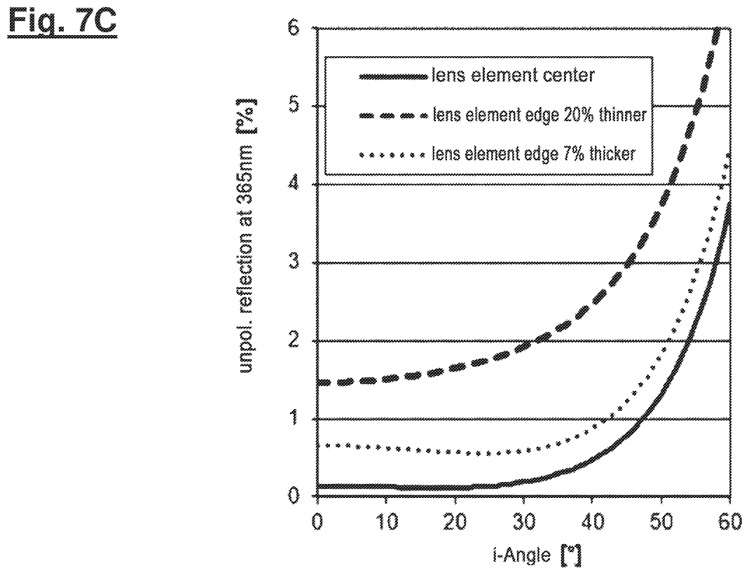

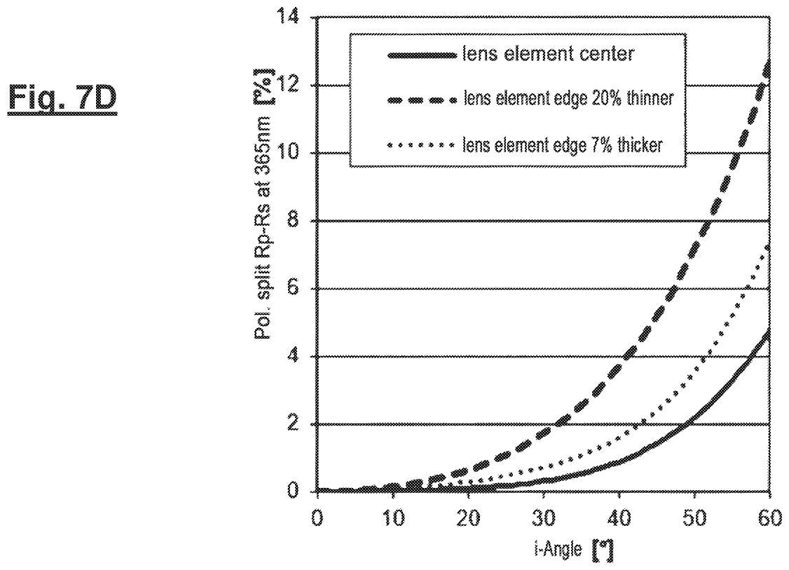

FIG. 4 shows a construction of a microlithographic projection exposure apparatus 400 designed for operation in the DUV that is possible in principle.

The projection exposure apparatus 400 according to FIG. 4 comprises an illumination device 410 and a projection lens 420. The illumination device 410 is used for illuminating a structure-bearing mask (reticle) 415 with light from a light source unit 405, which comprises a laser light source, for example in the form of an ArF excimer laser for a working wavelength of 193 nm (or in the form of a KrF excimer laser for a working wavelength of 248 nm or a mercury vapor lamp for a working wavelength of 365 nm) and a beam-shaping optical unit generating a parallel light beam. The laser light source can be designed in the manner according to the disclosed techniques.

The illumination device 410 has an optical unit 411, which comprises, among other things, a deflection mirror 412 in the example shown. The optical unit 411 may comprise, for example, a diffractive optical element (DOE) and a zoom-axicon system for generating different illumination settings (i.e., intensity distributions in a pupil plane of the illumination device 410). Arranged in the beam path downstream of the optical unit 411 in the direction of light propagation is a light mixing device (not shown), which can have, for example in a known manner, an arrangement of microoptical elements suitable for achieving light mixing, and a lens element group 413, downstream of which a field plane with a reticle masking system (REMA) is located, which is imaged by a REMA lens 414, which follows in the direction of light propagation, onto the structure-bearing mask (reticle) 415 arranged in a further field plane and thus delimits the illuminated region on the reticle. The structure-bearing mask 415 is imaged using the projection lens 420 onto a lens element substrate or a wafer 430 provided with a light-sensitive layer (photoresist). The projection lens 420 may be designed in particular for immersion operation, in which case an immersion medium is located upstream of the wafer or its light-sensitive layer with reference to the direction of light propagation. Further, it may, for example, have a numerical aperture NA of greater than 0.85, in particular greater than 1.1.

Although the disclosed techniques have also been described in special embodiments, numerous variations and alternative embodiments, e.g., by combining and/or exchanging features of individual embodiments, can be discerned by a person skilled in the art. Accordingly, it is understood by those skilled in the art that such variations and alternative embodiments are also comprised by the present invention, and the scope of the invention is limited only in the sense of the appended patent claims and their equivalents.

What is claimed is:

1. A lens element for a microlithographic projection exposure apparatus designed for operation in a Deep Ultraviolet (DUV) wavelength range, comprising:
a lens element substrate; and
an antireflection layer formed on the lens element substrate, wherein the antireflection layer has a first material of relatively lower refractive index and a second material of relatively higher refractive index, and wherein a mixing ratio between the first material and the second material varies both in a lateral direction and in a vertical direction.

2. The lens element of claim 1, further comprising at least one curved lens element surface.

3. A microlithographic projection exposure apparatus comprising at least one lens element as claimed in claim 1.

4. A method for forming an antireflection layer on a lens element substrate of a lens element for a microlithographic projection exposure apparatus designed for operation in a Deep Ultraviolet (DUV) wavelength range, the method comprising:
providing a lens element substrate; and
forming the antireflective layer on the lens substrate from a first material of relatively lower refractive index and at least one second material of relatively higher refractive index, wherein a mixing ratio between the first material and the second material is varied in a lateral direction and/or in a vertical direction, and wherein the antireflection layer is formed using separate evaporation sources for the first and second materials, wherein the material from these evaporation sources is respectively supplied via an intermittently open shutter.

5. The method of claim 4, wherein the lens element comprises at least one curved lens element surface.

6. The method of claim 4, wherein the evaporation sources are operated at a constant evaporation rate, wherein the variation of the mixing ratio is achieved by a targeted setting of respective opening durations of the shutters respectively assigned to the evaporation sources.

7. The method of claim 4, wherein a simultaneous evaporation from the evaporation sources is carried out, wherein an increase in an evaporation rate of the second material compared to an evaporation rate of the first material is synchronized with a variation of a respective currently coated region of the lens element substrate.

8. The method of claim 7, wherein the synchronization with the variation of the respective currently coated region of the lens element substrate comprises increasing, in a direction from a central region of the lens element to an edge region of the lens element, the evaporation rate of the second material compared to the evaporation rate of the first material.

9. The method as claimed in claim 7, wherein the variation of the currently coated region of the lens element substrate is implemented by variation of a relative position of an opening aperture located in a shading stop with respect to the lens element.

10. An arrangement for forming an antireflection layer on a lens element substrate of a lens element for a microlithographic projection exposure apparatus designed for operation in a Deep Ultraviolet (DUV) wavelength range, comprising:
a first evaporation source for a first material of relatively lower refractive index;
a second evaporation source for a second material of relatively higher refractive index; a first shutter assigned to the first evaporation source;
a second shutter assigned to the second evaporation source, and a device configured to intermittently open the first shutter and the second shutter.

11. The arrangement of claim 10, further comprising a shading stop and a device configured to vary a relative position of an opening aperture located in the shading stop with respect to the lens element.

12. The arrangement of claim 11, wherein the device configured to vary the relative position of the opening aperture with respect to the lens element is configured to vary the relative position in synchronization with an increase in an evaporation rate of the second material compared to an evaporation rate of the first material.
